(19) United States
(12) Patent Application Publication
(10) Pub. No.: US 2026/0305439 A1
(43) Pub. Date: Oct. 1, 2026

(54) SEMICONDUCTOR STRUCTURE AND FABRICATION METHOD THEREOF

(71) Applicant: UNITED MICROELECTRONICS CORP., Hsin-Chu City (TW)

(72) Inventors: Tsung-Kai Yu, Hsinchu County (TW); Chen-Hsiao Wang, Hsinchu City (TW); Kai-Kuang Ho, Hsinchu City (TW)

(73) Assignee: UNITED MICROELECTRONICS CORP., Hsin-Chu City (TW)

(21) Appl. No.: 19/177,616

(22) Filed: Apr. 13, 2025

(30) Foreign Application Priority Data
Mar. 26, 2025 (TW) 114111466

(51) Int. Cl. H10W 72/20; H10W 72/00; H10W 72/90; H10W 72/29

(52) U.S. Cl. CPC H10W 72/20; H10W 72/012; H10W 72/019; H10W 72/90; H10W 72/01235; H10W 72/01251; H10W 72/01255; H10W 72/01257; H10W 72/01935; H10W 72/01938; H10W 72/01955; H10W 72/234; H10W 72/29; H10W 72/921; H10W 72/923; H10W 72/924; H10W 72/934; H10W 72/952

(57) ABSTRACT

A semiconductor structure includes a substrate having a bump pad thereon and a passivation layer disposed on the substrate. The passivation layer covers a perimeter of the bump pad and has a slot-shaped opening exposing a central region of the bump pad. An under bump metal (UBM) layer is disposed on the central region of the bump pad. A solder bump is disposed on the UBM layer. The solder bump has a flat top surface area.

### BACKGROUND OF THE INVENTION

### 1. Field of the Invention

The present invention relates to the field of semiconductor technology, and more particularly, to an improved semiconductor structure and a fabrication method thereof.

### 2. Description of the Prior Art

In semiconductor wafer manufacturing, bumps are an important component for connecting the chip to external circuits. However, when using probing tips to perform electrical testing of the chips, such as chip probing (CP testing), existing bump structures, especially solder bar bump structures, encounter some problems. Solder bar bump designs are often used for high-current components, so during CP testing, each solder bar bump structure typically contacts multiple probes to distribute the current.

However, since the surface of the solder bar bump structure is arc-shaped, during CP testing, the insufficient contact area between the probes and the bump structure easily leads to the problem of burnt probes. This is because the surface of the solder bar bump structure is not flat enough, making it difficult for the probes to make effective contact, resulting in excessive resistance and localized overheating.

### SUMMARY OF THE INVENTION

It is one objective of the present invention to provide an improved semiconductor structure and a fabrication method thereof, so as to solve the aforementioned deficiencies or shortcomings of the prior art.

One aspect of the invention provides a semiconductor structure including a substrate having a bump pad thereon; a passivation layer disposed on the substrate, wherein the passivation layer covers a perimeter of the bump pad and has a slot-shaped opening exposing a central region of the bump pad; an under bump metal (UBM) layer disposed on the central region of the bump pad; and a solder bump disposed on the UBM layer, wherein the solder bump comprises a flat top surface area.

According to some embodiments, the slot-shaped opening has a length L and a width W, wherein an L/W ratio is equal to or greater than 1.

According to some embodiments, the solder bump further comprises a vertical sidewall.

According to some embodiments, the solder bump further comprises a rounded corner between the vertical sidewall and the flat top surface area.

According to some embodiments, the bump pad comprises an aluminum pad.

Another aspect of the invention provides a method for forming a semiconductor structure including the steps of: providing a substrate having a bump pad thereon; forming a passivation layer on the substrate, wherein the passivation layer covers a perimeter of the bump pad and has a slot-shaped opening exposing a central region of the bump pad; forming an under bump metal (UBM) layer on the central region of the bump pad; forming a solder bump on the UBM layer; subjecting the solder bump to a re-flow process; and after the re-flow process, pressing the solder bump with a jig at a predetermined temperature thereby forming a flat top surface area on the solder bump.

According to some embodiments, the slot-shaped opening has a length L and a width W, wherein an L/W ratio is equal to or greater than 1.

According to some embodiments, the solder bump further comprises a vertical sidewall.

According to some embodiments, the solder bump further comprises a rounded corner between the vertical sidewall and the flat top surface area.

According to some embodiments, the bump pad comprises an aluminum pad.

According to some embodiments, the predetermined temperature is between 250-280 degrees Celsius.

Another aspect of the invention provides a semiconductor structure including a substrate having a bump pad thereon; a first passivation layer disposed on the substrate, wherein the first passivation layer covers a perimeter of the bump pad and has a first slot-shaped opening exposing a central region of the bump pad; a second passivation layer disposed on the first passivation layer, wherein the second passivation layer has a second slot-shaped opening overlapping with the first slot-shaped opening, wherein the second slot-shaped opening has a dimension that is greater than a dimension of the first slot-shaped opening; an under bump metal (UBM) layer disposed on the central region of the bump pad; and a solder bump filled into the first slot-shaped opening and the second slot-shaped opening.

According to some embodiments, the slot-shaped opening has a length L and a width W, wherein an L/W ratio is equal to or greater than 1.

According to some embodiments, the second slot-shaped opening is concentric and completely overlapped with the first slot-shaped opening.

According to some embodiments, a step structure is provided between the second slot-shaped opening and the first slot-shaped opening.

According to some embodiments, the second passivation layer has a declined sidewall around the second slot-shaped opening, and wherein the UBM layer covers the declined sidewall.

Still another aspect of the invention provides a semiconductor structure including a substrate having a bump pad thereon; a passivation layer disposed on the substrate, wherein the passivation layer covers a perimeter of the bump pad and has a slot-shaped opening exposing a central region of the bump pad; a first copper layer disposed on the bump pad; an annular second copper layer disposed along the perimeter of the bump pad, wherein the annular second copper layer partially overlaps the first copper layer, and wherein an opening is defined by the annular second copper layer; and a solder bump filled into the opening.

According to some embodiments, the slot-shaped opening has a length L and a width W, wherein an L/W ratio is equal to or greater than 1.

According to some embodiments, the solder bump extends onto a top surface of the annular second copper layer.

According to some embodiments, a thickness of the annular second copper layer is greater than a thickness of the first copper layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top schematic view illustrating a bar-shaped bump structure according to an embodiment of the present invention.

FIG. 2 is a cross-sectional schematic view taken along the line I-I’ in FIG. 1.

FIG. 3 is a top schematic view illustrating a spherical bump structure according to another embodiment of the present invention.

FIG. 4 is a cross-sectional schematic view taken along the line II-II’ in FIG. 3.

FIGS. 5-8 illustrate the steps of forming the bar-shaped bump structure in FIG. 2.

FIG. 9 is a cross-sectional schematic view illustrating a bump structure according to another embodiment of the present invention.

FIG. 10 is a cross-sectional schematic view illustrating a bump structure according to yet another embodiment of the present invention.

FIGS. 11-20 illustrate the steps of forming the bump structure in FIG. 9.

FIG. 21 illustrates the step of forming the bump structure in FIG. 10.

FIG. 22 is a cross-sectional schematic view illustrating a bump structure according to yet another embodiment of the present invention.

FIG. 23 is a cross-sectional schematic view illustrating a bump structure according to yet another embodiment of the present invention.

FIGS. 24-34 illustrate the steps of forming the bump structure in FIG. 22.

FIG. 35 illustrates the step of forming the bump structure in FIG. 23.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

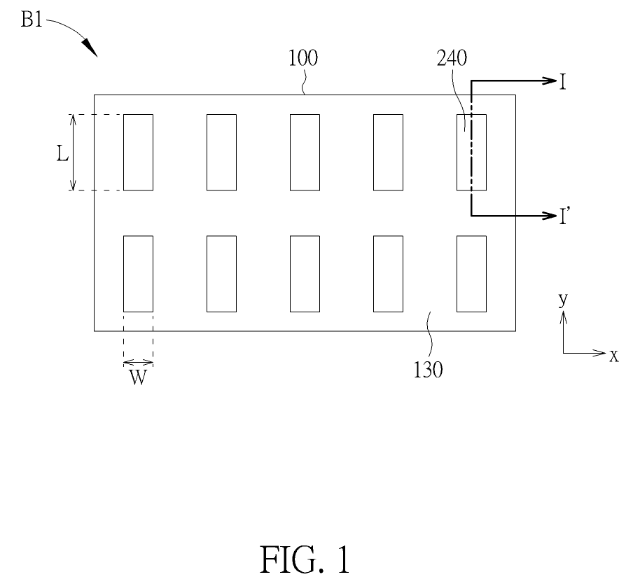

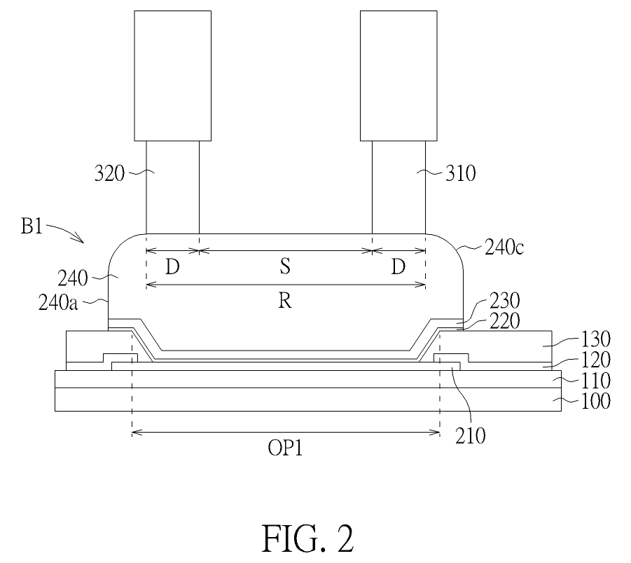

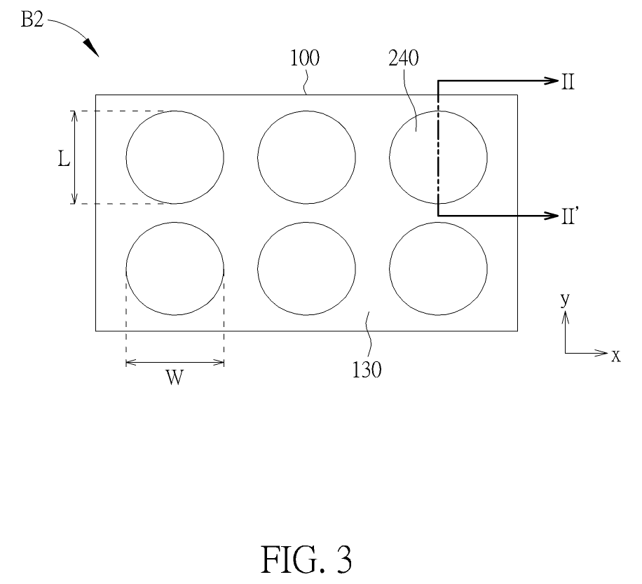

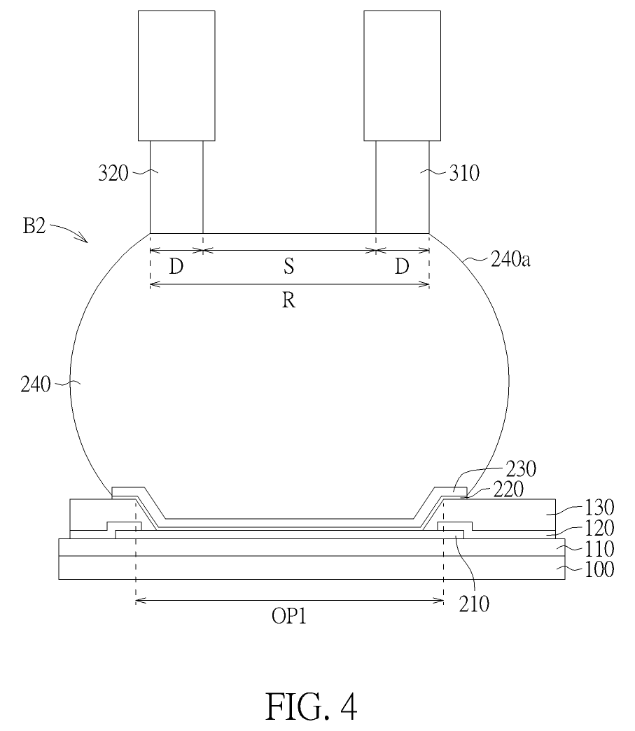

Please refer to FIGS. 1-4, wherein FIG. 1 is a top schematic view illustrating a bar-shaped bump structure according to an embodiment of the present invention, FIG. 2 is a cross-sectional schematic view taken along the line I-I’ in FIG. 1, FIG. 3 is a top schematic view illustrating a spherical bump structure according to another embodiment of the present invention, and FIG. 4 is a cross-sectional schematic view taken along the line II-II’ in FIG. 3. As shown in FIGS. 1 and 3, the bump structures B1 and B2 respectively have elongated solder bumps 240 and spherical solder bumps 240, which have a length L in the y-axis direction and a width W in the x-axis direction, and the elongated solder bump 240 in FIG. 1 has an L/W ratio greater than 1, while the spherical solder bump 240 in FIG. 3 has an L/W ratio approximately equal to 1.

As shown in FIGS. 1 and 2, the bump structure B1 is disposed on a substrate 100, for example, a silicon substrate or a GaN substrate, but not limited thereto. At least one dielectric layer 110, for example, a silicon oxide layer, but not limited thereto, is disposed on the substrate 100. In addition, a bump pad 210 is disposed on the dielectric layer 110. According to an embodiment of the present invention, the bump pad 210 includes, for example, an aluminum pad. According to an embodiment of the present invention, passivation layers 120 and 130 are further disposed on the substrate 100, wherein the passivation layers 120 and 130 cover the periphery of the bump pad 210 and have a slot-shaped opening OP1, which approximately has a length L in the y-axis direction and a width W in the x-axis direction, and the L/W ratio is greater than 1. According to an embodiment of the present invention, the passivation layers 120 and 130 can include, for example, polyimide (PI), polybenzoxazole (PBO), benzocyclobutene (BCB), but not limited thereto.

According to an embodiment of the present invention, the slot-shaped opening OP1 exposes the central region of the bump pad 210. According to an embodiment of the present invention, a sputtering layer 220, an under bump metal (UBM) layer 230, and a solder bump 240 are sequentially formed on the central region of the bump pad 210. According to an embodiment of the present invention, the solder bump 240 is disposed on the UBM layer 230. According to an embodiment of the present invention, the sputtering layer 220 is, for example, TiW/Cu or Ti/Cu. According to an embodiment of the present invention, the UBM layer 230 is, for example, Ni, Cu, or Cu/Ni/Au. According to an embodiment of the present invention, the solder bump 240 may contain tin or any suitable solder material.

In order to avoid insufficient contact area between the probing tips 310 and 320 and the solder bump 240 causing burnt probes, a flat top surface area R is formed on the solder bump 240 to provide sufficient contact area for the probing tips 310 and 320 during CP testing. For example, if the size D (width in the y-axis direction) of the probing tips 310 and 320 is 75um and the pitch S is 150um, then the required width of the flat top surface area R in the y-axis direction for the two probing tips 310 and 320 is 300um (i.e., R≥2D+S).

According to an embodiment of the present invention, the solder bump 240 may further include a vertical sidewall 240a. According to an embodiment of the present invention, the solder bump 240 further includes a rounded corner 240c located between the vertical sidewall 240a and the flat top surface area R.

As shown in FIGS. 3 and 4, similarly, the bump structure B2 is disposed on a substrate 100, for example, a silicon substrate or a GaN substrate, but not limited thereto. At least one dielectric layer 110, for example, a silicon oxide layer, but not limited thereto, is disposed on the substrate 100. In addition, a bump pad 210 is disposed on the dielectric layer 110. According to an embodiment of the present invention, the bump pad 210 includes, for example, an aluminum pad. According to an embodiment of the present invention, passivation layers 120 and 130 are further disposed on the substrate 100, wherein the passivation layers 120 and 130 cover the periphery of the bump pad 210 and have a slot-shaped opening OP1, which approximately has a length L in the y-axis direction and a width W in the x-axis direction, and the L/W ratio is approximately equal to 1. According to an embodiment of the present invention, the passivation layers 120 and 130 can include, for example, PI, PBO, BCB, but not limited thereto.

According to an embodiment of the present invention, the slot-shaped opening OP1 exposes the central region of the bump pad 210. According to an embodiment of the present invention, a sputtering layer 220, a UBM layer 230, and a solder bump 240 are sequentially formed on the central region of the bump pad 210. According to an embodiment of the present invention, the solder bump 240 is disposed on the UBM layer 230. According to an embodiment of the present invention, the sputtering layer 220 is, for example, TiW/Cu or Ti/Cu. According to an embodiment of the present invention, the UBM layer 230 is, for example, Ni, Cu, or Cu/Ni/Au. According to an embodiment of the present invention, the solder bump 240 may contain tin or any suitable solder material.

Likewise, a flat top surface area R is formed on the solder bump 240 to provide sufficient contact area for the probing tips 310 and 320 during CP testing. For example, if the size D (width in the y-axis direction) of the probing tips 310 and 320 is 75um and the pitch S is 150um, then the required width of the flat top surface area R in the y-axis direction for the two probing tips 310 and 320 is 300um.

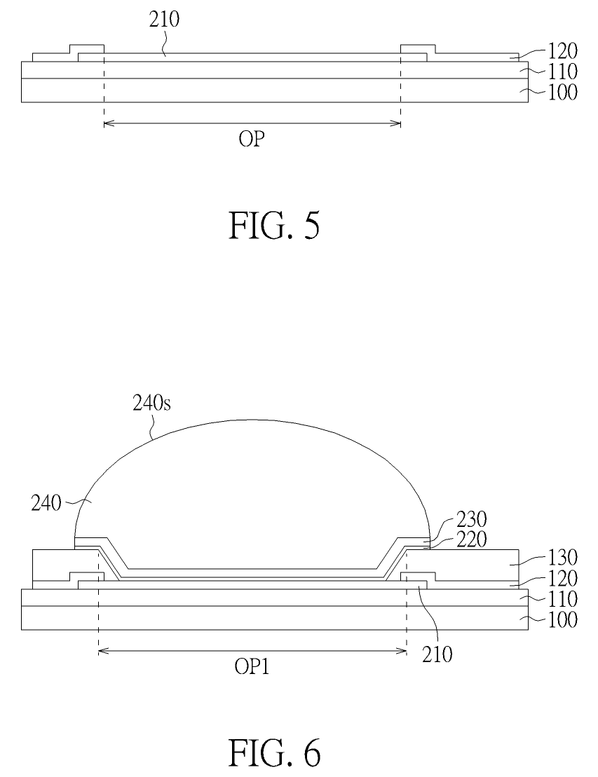

Please refer to FIGS. 5-8, which illustrate the steps of forming the bar-shaped bump structure in FIG. 2. As shown in FIG. 5, a substrate 100 is first provided, for example, a silicon substrate or a GaN substrate, but not limited thereto. Next, at least one dielectric layer 110, for example, a silicon oxide layer, but not limited thereto, is formed on the substrate 100. A bump pad 210 is then formed on the dielectric layer 110. According to an embodiment of the present invention, the bump pad 210 includes, for example, an aluminum pad. A passivation layer 120 is then formed on the substrate 100, and the passivation layer 120 covers the periphery of the bump pad 210 and forms a slot-shaped opening OP.

Next, as shown in FIG. 6, another passivation layer 130 is formed on the substrate 100, wherein the passivation layer 130 covers the periphery of the bump pad 210 and forms a slot-shaped opening OP1, the size of which can be approximately equal to the slot-shaped opening OP. According to an embodiment of the present invention, the passivation layers 120 and 130 can include, for example, PI, PBO, BCB, but not limited thereto.

Next, a bumping process is performed, in which a sputtering layer 220, a UBM layer 230, and a solder bump 240 are sequentially formed on the central region of the bump pad 210. According to an embodiment of the present invention, the solder bump 240 is disposed on the UBM layer 230. According to an embodiment of the present invention, the sputtering layer 220 is, for example, TiW/Cu or Ti/Cu. According to an embodiment of the present invention, the UBM layer 230 is, for example, Ni, Cu, or Cu/Ni/Au. According to an embodiment of the present invention, the solder bump 240 may contain tin or any suitable solder material. After undergoing a reflow process, the solder bump 240 has a spherical surface 240s. According to an embodiment of the present invention, as shown in FIG. 1, the solder bump 240 has a length L and a width W, and the L/W ratio is greater than 1.

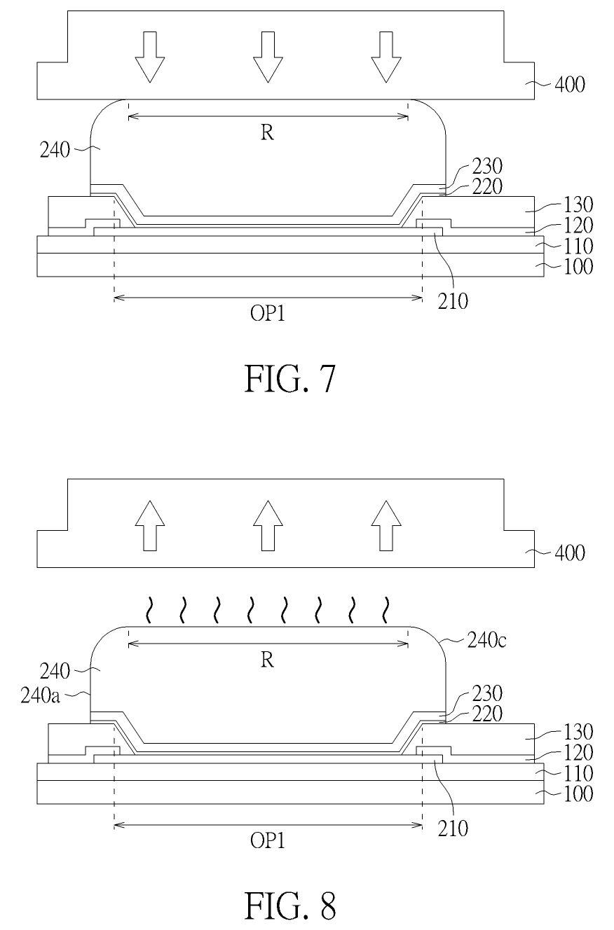

As shown in FIG. 7, a bump hot pressing process is performed, in which a jig 400 is used to press the solder bump 240 at a predetermined temperature, softening and pressing down the already formed solder bump 240, thereby forming a flat top surface area R on the solder bump 240. As shown in FIG. 8, the jig 400 is finally removed and the solder bump 240 is cooled. According to an embodiment of the present invention, the jig 400 is, for example, a hot press plate, and the aforementioned predetermined temperature is, for example, between 250 and 280 degrees Celsius.

Please refer to FIG. 9, which is a cross-sectional schematic view illustrating a bump structure according to another embodiment of the present invention. As shown in FIG. 9, the bump structure B3 is also disposed on a substrate 100, for example, a silicon substrate or a GaN substrate, but not limited thereto. The top view of the bump structure B3 can be a bar-shaped bump structure as shown in FIG. 1, or a spherical bump structure as shown in FIG. 3.

According to an embodiment of the present invention, at least one dielectric layer 110, for example, a silicon oxide layer, but not limited thereto, is disposed on the substrate 100. In addition, a bump pad 210 is disposed on the dielectric layer 110. According to an embodiment of the present invention, the bump pad 210 includes, for example, an aluminum pad. According to an embodiment of the present invention, passivation layers 120 and 131-134 are further disposed on the substrate 100, wherein the passivation layers 120 and 131 cover the periphery of the bump pad 210 and have a slot-shaped opening OP1, which approximately has a length L in the y-axis direction and a width W in the x-axis direction as shown in FIG. 1, and the L/W ratio is greater than 1. According to an embodiment of the present invention, the passivation layers 120 and 131-134 can include, for example, PI, PBO, BCB, but not limited thereto. According to an embodiment of the present invention, for example, the thickness of each passivation layer 131-134 can be approximately 20 micrometers.

FIG. 9 illustrates four passivation layers 131-134. However, it should be understood that in other embodiments, there can also be two or more passivation layers.

According to an embodiment of the present invention, the passivation layer 131 covers the periphery of the bump pad 210 and has a slot-shaped opening OP1, exposing the central region of the bump pad 210. According to an embodiment of the present invention, the passivation layer 132 is disposed on the passivation layer 131, wherein the passivation layer 132 has a slot-shaped opening OP2 that completely overlaps with the slot-shaped opening OP1, and wherein the size of the slot-shaped opening OP2 is larger than the size of the slot-shaped opening OP1. According to an embodiment of the present invention, the passivation layer 133 is disposed on the passivation layer 132, wherein the passivation layer 133 has a slot-shaped opening OP3 that completely overlaps with the slot-shaped opening OP2, and wherein the size of the slot-shaped opening OP3 is larger than the size of the slot-shaped opening OP2. According to an embodiment of the present invention, the passivation layer 134 is disposed on the passivation layer 133, wherein the passivation layer 134 has a slot-shaped opening OP4 that completely overlaps with the slot-shaped opening OP3, and wherein the size of the slot-shaped opening OP4 is larger than the size of the slot-shaped opening OP3.

According to an embodiment of the present invention, the slot-shaped openings OP1-OP4 are concentric and completely overlap each other. According to an embodiment of the present invention, there is a stepped structure between the slot-shaped openings OP1-OP4. According to an embodiment of the present invention, the passivation layers 131-134 have inclined sidewalls SW1-SW4 around the slot-shaped openings OP1-OP4, respectively.

According to an embodiment of the present invention, a sputtering layer 220, a UBM layer 230, and a solder bump 240 are sequentially formed on the central region of the bump pad 210 within the slot-shaped openings OP1-OP4. According to an embodiment of the present invention, the solder bump 240 is disposed on the UBM layer 230. According to an embodiment of the present invention, the sputtering layer 220 is, for example, TiW/Cu or Ti/Cu. According to an embodiment of the present invention, the UBM layer 230 is, for example, Ni, Cu, or Cu/Ni/Au. According to an embodiment of the present invention, the solder bump 240 may contain tin or any suitable solder material.

According to an embodiment of the present invention, the solder bump 240 may have an inverted pyramid-shaped cross-sectional profile. According to an embodiment of the present invention, the sputtering layer 220 and the UBM layer 230 conformally cover the inclined sidewalls SW1-SW4. The solder bump 240 after the reflow process has a relatively flat upper surface, which can avoid the problem of burnt probes due to insufficient contact area between the probes and the solder bump 240.

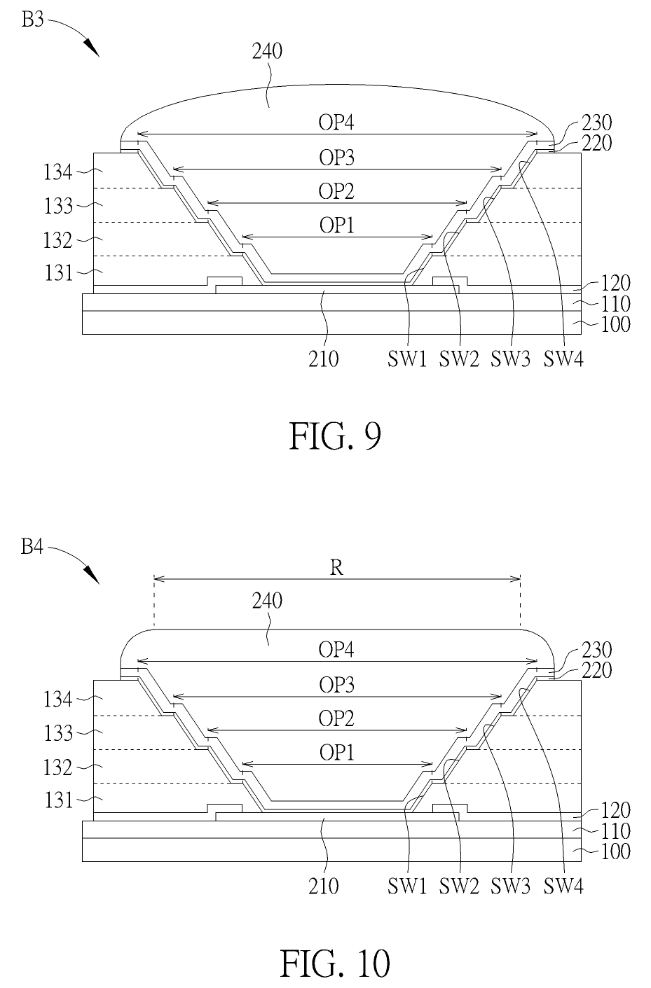

Please refer to FIG. 10, which is a cross-sectional schematic view illustrating a bump structure according to yet another embodiment of the present invention. As shown in FIG. 10, the bump structure B3 in FIG. 9 can be further subjected to a bump hot pressing process, in which a jig (as shown in FIGS. 7-8) is used to press the solder bump 240 at a predetermined temperature, softening and pressing down the already formed solder bump 240, thereby forming a flat top surface area R on the solder bump 240, thus forming the bump structure B4.

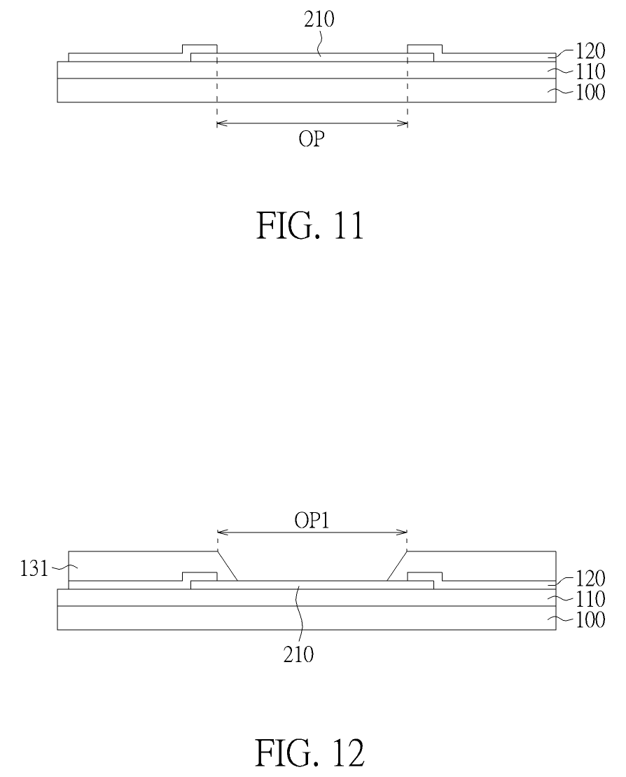

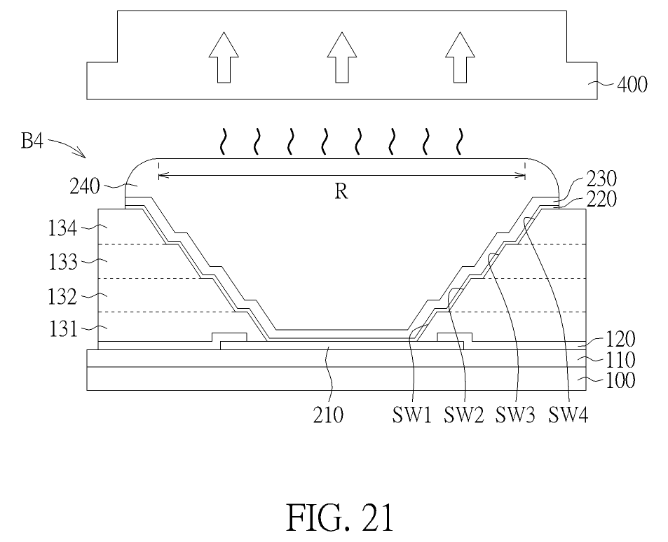

Please refer to FIGS. 11-21, wherein FIGS. 11-20 illustrate the steps of forming the bump structure in FIG. 9, and FIG. 21 illustrates the step of forming the bump structure in FIG. 10. As shown in FIG. 11, a substrate 100 is first provided, for example, a silicon substrate or a GaN substrate, but not limited thereto. Next, at least one dielectric layer 110, for example, a silicon oxide layer, but not limited thereto, is formed on the substrate 100. A bump pad 210 is then formed on the dielectric layer 110. According to an embodiment of the present invention, the bump pad 210 includes, for example, an aluminum pad. A passivation layer 120 is then formed on the substrate 100, and the passivation layer 120 covers the periphery of the bump pad 210 and forms a slot-shaped opening OP.

Next, as shown in FIG. 12, another passivation layer 131 is formed on the substrate 100, wherein the passivation layer 131 covers the periphery of the bump pad 210 and forms a slot-shaped opening OP1, the size of which can be approximately equal to the slot-shaped opening OP.

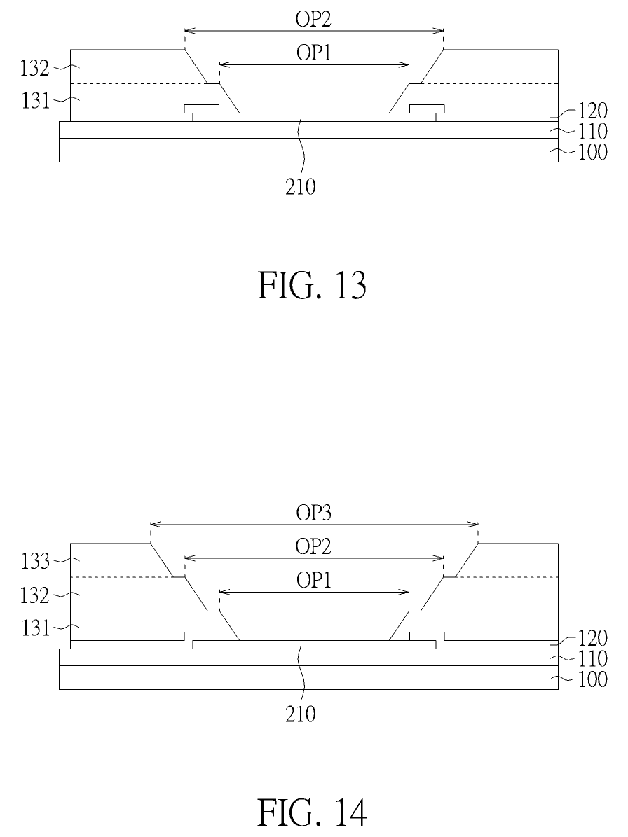

As shown in FIGS. 13-15, passivation layers 132-134 are sequentially formed on the substrate 100, wherein the passivation layer 132 has a slot-shaped opening OP2 that completely overlaps with the slot-shaped opening OP1, the passivation layer 133 has a slot-shaped opening OP3 that completely overlaps with the slot-shaped opening OP2, and the passivation layer 134 has a slot-shaped opening OP4 that completely overlaps with the slot-shaped opening OP3, wherein the size of the slot-shaped opening OP4 is larger than the size of the slot-shaped opening OP3, the size of the slot-shaped opening OP3 is larger than the size of the slot-shaped opening OP2, and the size of the slot-shaped opening OP2 is larger than the size of the slot-shaped opening OP1.

According to an embodiment of the present invention, the slot-shaped openings OP1-OP4 are concentric and completely overlap each other. According to an embodiment of the present invention, there is a stepped structure between the slot-shaped openings OP1-OP4.

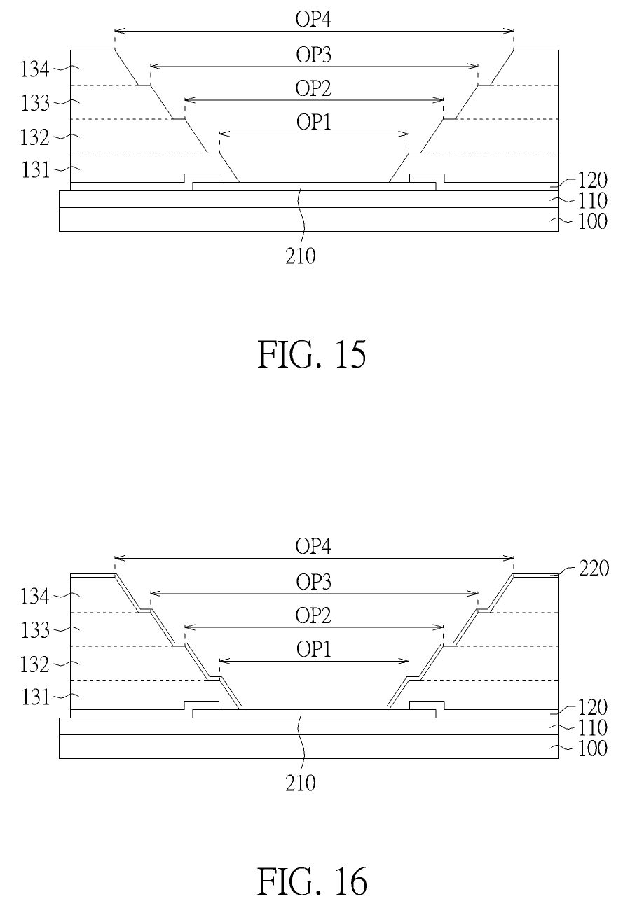

As shown in FIG. 16, next, a sputtering layer 220 is deposited over the entire substrate 100. According to an embodiment of the present invention, the sputtering layer 220 is conformally deposited within the slot-shaped openings OP1-OP4. According to an embodiment of the present invention, the sputtering layer 220 is, for example, TiW/Cu or Ti/Cu.

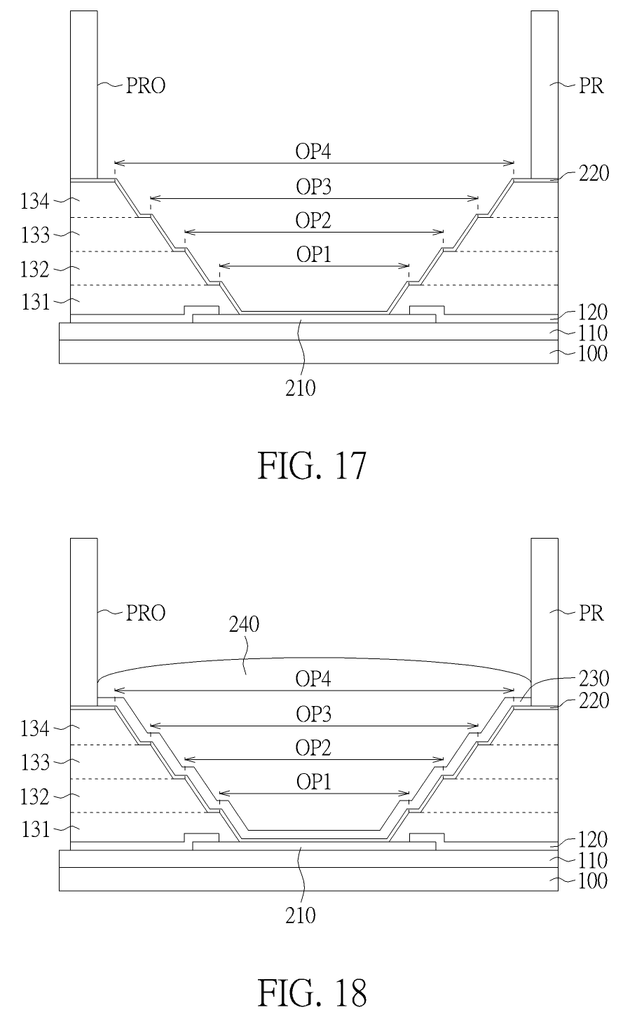

As shown in FIG. 17, a photoresist pattern PR is then formed on the sputtering layer 220, which has an opening PRO defining the position and pattern of the bump to be formed.

As shown in FIG. 18, an electroplating process can then be performed to form the UBM layer 230 and the solder bump 240 within the opening PRO and the slot-shaped openings OP1-OP4. According to an embodiment of the present invention, the UBM layer 230 is, for example, Ni, Cu, or Cu/Ni/Au. According to an embodiment of the present invention, the solder bump 240 may contain tin or any suitable solder material.

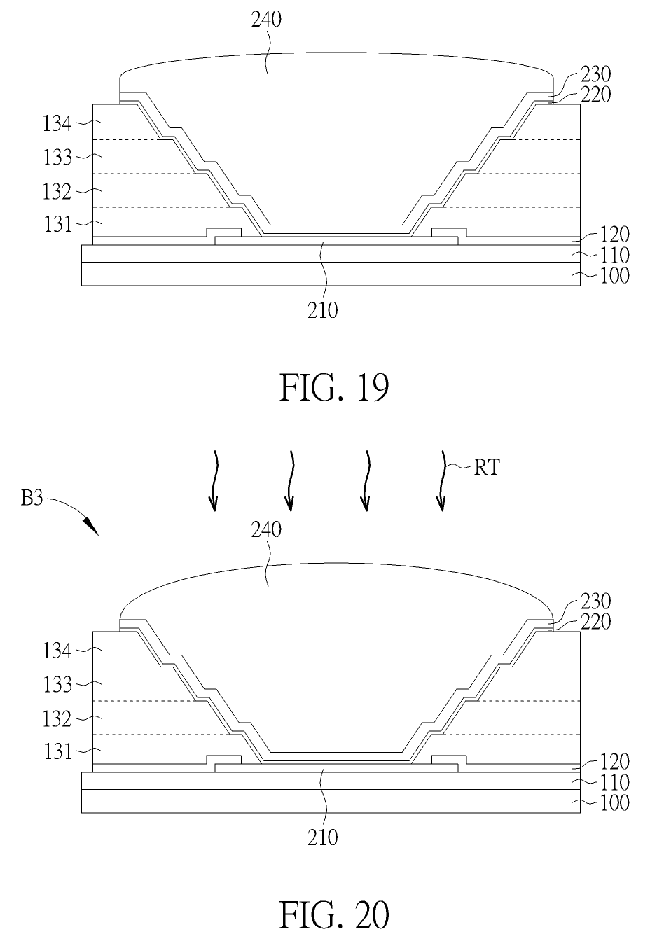

As shown in FIG. 19, the photoresist pattern PR is then removed. An etching process is then performed to remove the sputtering layer 220 that was originally directly under the photoresist pattern PR.

As shown in FIG. 20, a reflow process is then performed, thus completing the bump structure B3 in FIG. 9.

As shown in FIG. 21, the bump structure B3 in FIG. 9 can be further subjected to a bump hot pressing process, in which a jig (as shown in FIGS. 7-8) is used to press the solder bump 240 at a predetermined temperature, softening and pressing down the already formed solder bump 240, thereby forming a flat top surface area R on the solder bump 240, thus forming the bump structure B4 in FIG. 10.

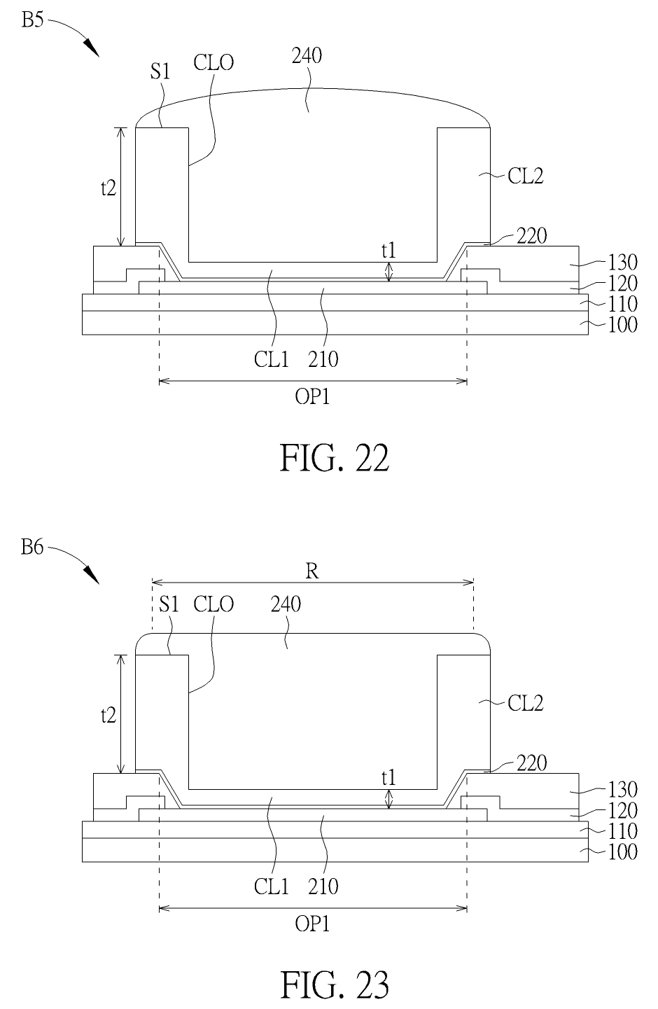

Please refer to FIG. 22, which is a cross-sectional schematic view illustrating a bump structure according to yet another embodiment of the present invention. As shown in FIG. 22, the bump structure B5 is also disposed on a substrate 100, for example, a silicon substrate or a GaN substrate, but not limited thereto. The top view of the bump structure B5 can be a bar-shaped bump structure as shown in FIG. 1, or a spherical bump structure as shown in FIG. 3.

According to an embodiment of the present invention, at least one dielectric layer 110, for example, a silicon oxide layer, but not limited thereto, is disposed on the substrate 100. In addition, a bump pad 210 is disposed on the dielectric layer 110. According to an embodiment of the present invention, the bump pad 210 includes, for example, an aluminum pad. According to an embodiment of the present invention, passivation layers 120 and 130 are further disposed on the substrate 100, wherein the passivation layers 120 and 130 cover the periphery of the bump pad 210 and have a slot-shaped opening OP1, exposing the central region of the bump pad 210. According to an embodiment of the present invention, the passivation layers 120 and 130 can include, for example, PI, PBO, BCB, but not limited thereto.

According to an embodiment of the present invention, the slot-shaped opening OP1 approximately has a length L in the y-axis direction and a width W in the x-axis direction as shown in FIG. 1, and the L/W ratio is greater than 1.

According to an embodiment of the present invention, a first copper layer CL1 with a thickness t1 of approximately 4-20 micrometers is disposed on the bump pad 210. According to an embodiment of the present invention, an annular second copper layer CL2 with a thickness t2 of approximately 15-135 micrometers is disposed around the periphery of the bump pad 210. According to an embodiment of the present invention, the annular second copper layer CL2 partially overlaps the first copper layer CL1. The annular second copper layer CL2 defines an opening CLO, the shape of which is similar to the slot-shaped opening OP1, and a solder bump 240 is filled into the opening.

According to an embodiment of the present invention, the solder bump 240 extends to the top surface S1 of the annular second copper layer CL2. According to an embodiment of the present invention, the thickness t2 of the annular second copper layer CL2 is greater than the thickness t1 of the first copper layer CL1.

Please refer to FIG. 23, which is a cross-sectional schematic view illustrating a bump structure according to yet another embodiment of the present invention. As shown in FIG. 23, the bump structure B5 in FIG. 22 can be further subjected to a bump hot pressing process, in which a jig (as shown in FIGS. 7-8) is used to press the solder bump 240 at a predetermined temperature, softening and pressing down the already formed solder bump 240, thereby forming a flat top surface area R on the solder bump 240, thus forming the bump structure B6.

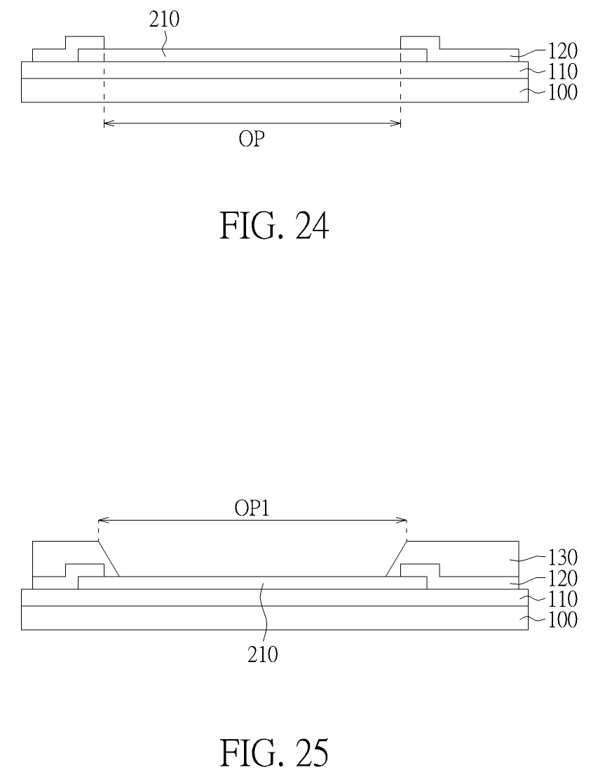

Please refer to FIGS. 24-35, wherein FIGS. 24-34 illustrate the steps of forming the bump structure in FIG. 22, and FIG. 35 illustrates the step of forming the bump structure in FIG. 23. As shown in FIG. 24, a substrate 100 is first provided, for example, a silicon substrate or a GaN substrate, but not limited thereto. Next, at least one dielectric layer 110, for example, a silicon oxide layer, but not limited thereto, is formed on the substrate 100. A bump pad 210 is then formed on the dielectric layer 110. According to an embodiment of the present invention, the bump pad 210 includes, for example, an aluminum pad. A passivation layer 120 is then formed on the substrate 100, and the passivation layer 120 covers the periphery of the bump pad 210 and forms a slot-shaped opening OP.

Next, as shown in FIG. 25, another passivation layer 130 is formed on the substrate 100, wherein the passivation layer 130 covers the periphery of the bump pad 210 and forms a slot-shaped opening OP1, the size of which can be approximately equal to the slot-shaped opening OP.

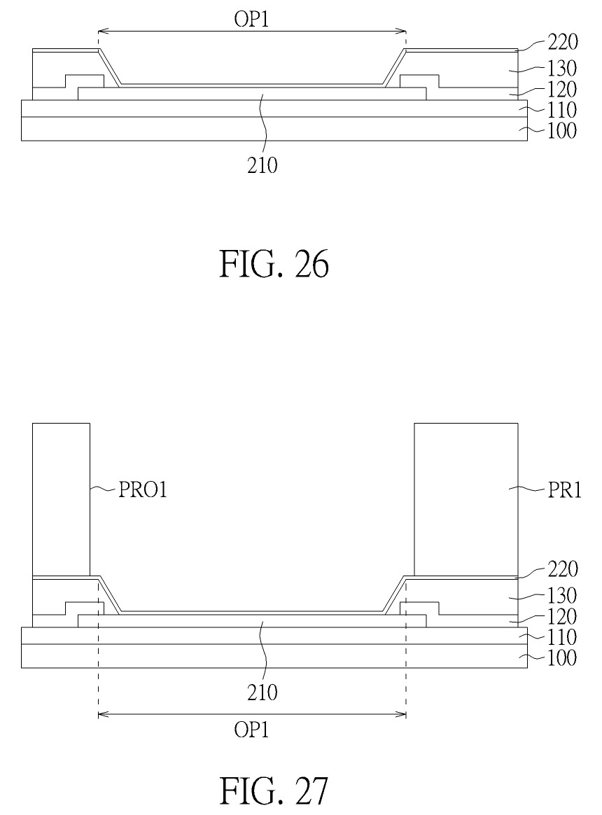

As shown in FIG. 26, next, a sputtering layer 220 is deposited over the entire substrate 100. According to an embodiment of the present invention, the sputtering layer 220 is conformally deposited within the slot-shaped opening OP1 and on the passivation layer 130. According to an embodiment of the present invention, the sputtering layer 220 is, for example, TiW/Cu or Ti/Cu.

As shown in FIG. 27, a photoresist pattern PR1 is then formed on the sputtering layer 220, which has an opening PRO1 defining the position and pattern of the bump to be formed.

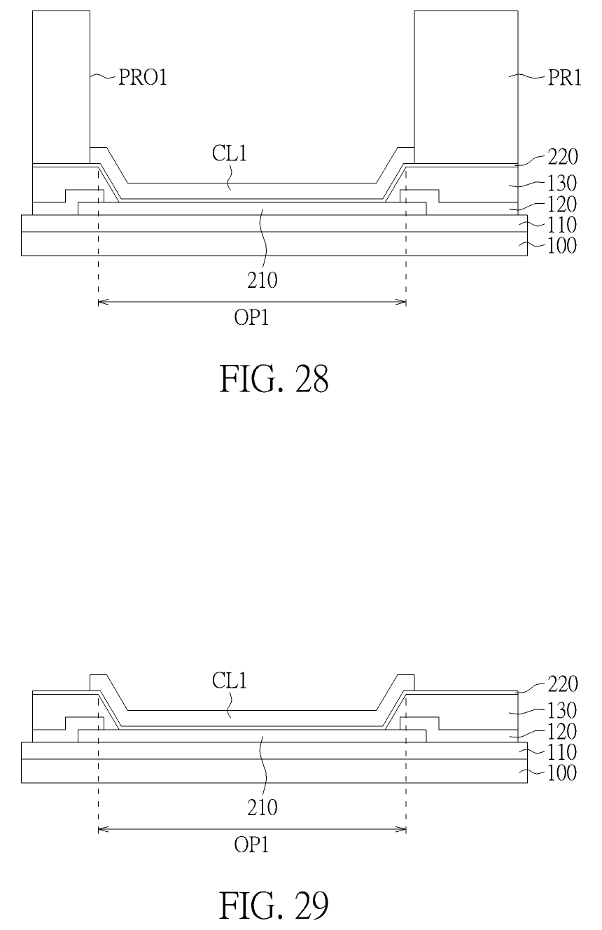

As shown in FIG. 28, an electroplating process can then be performed to form the first copper layer CL1 within the opening PRO1 and the slot-shaped opening OP1, the thickness of which is, for example, approximately 4-20 micrometers.

As shown in FIG. 29, the photoresist pattern PR1 is then removed.

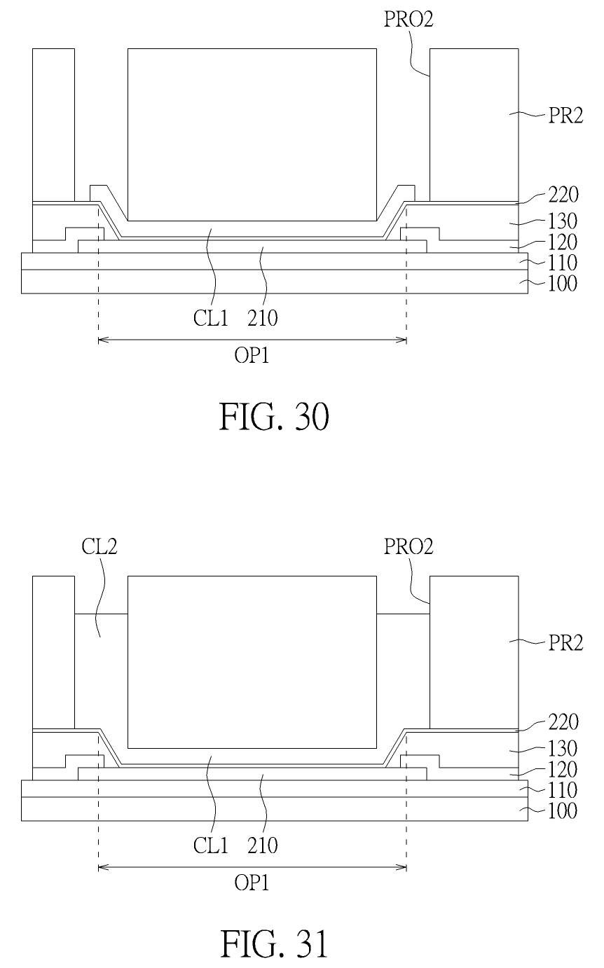

As shown in FIG. 30, a photoresist pattern PR2 is formed on the first copper layer CL1 and the sputtering layer 220, which has an opening PRO2 exposing a portion of the first copper layer CL1 and the sputtering layer 220 around the periphery of the bump pad 210.

As shown in FIG. 31, an electroplating process can then be performed to form the annular second copper layer CL2 within the opening PRO2, the thickness of which is, for example, approximately 15-135 micrometers. The annular second copper layer CL2 defines an opening CLO, the shape of which is similar to the slot-shaped opening OP1.

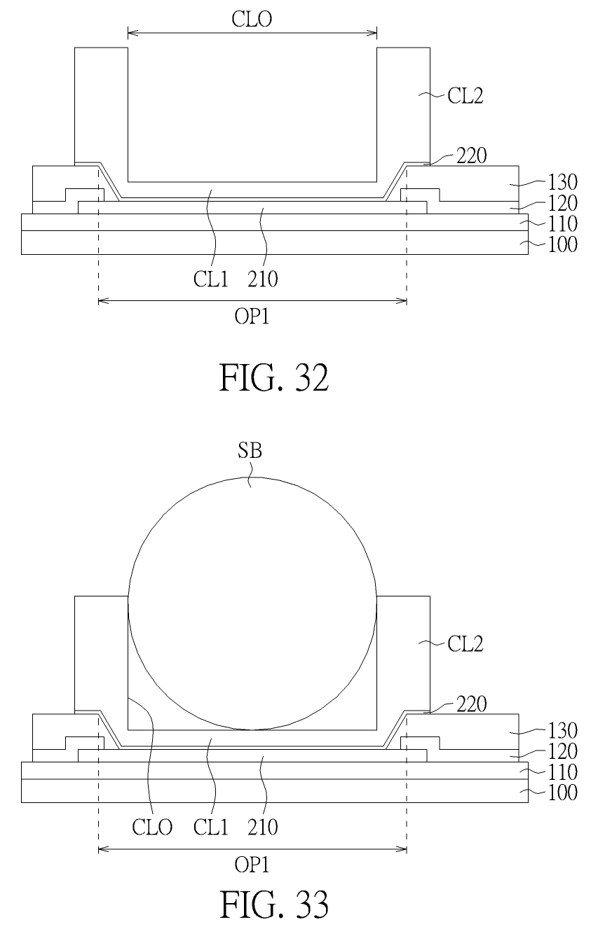

As shown in FIG. 32, the photoresist pattern PR2 is then removed.

As shown in FIG. 33, next, a solder ball SB is placed within the opening CLO defined by the annular second copper layer CL2.

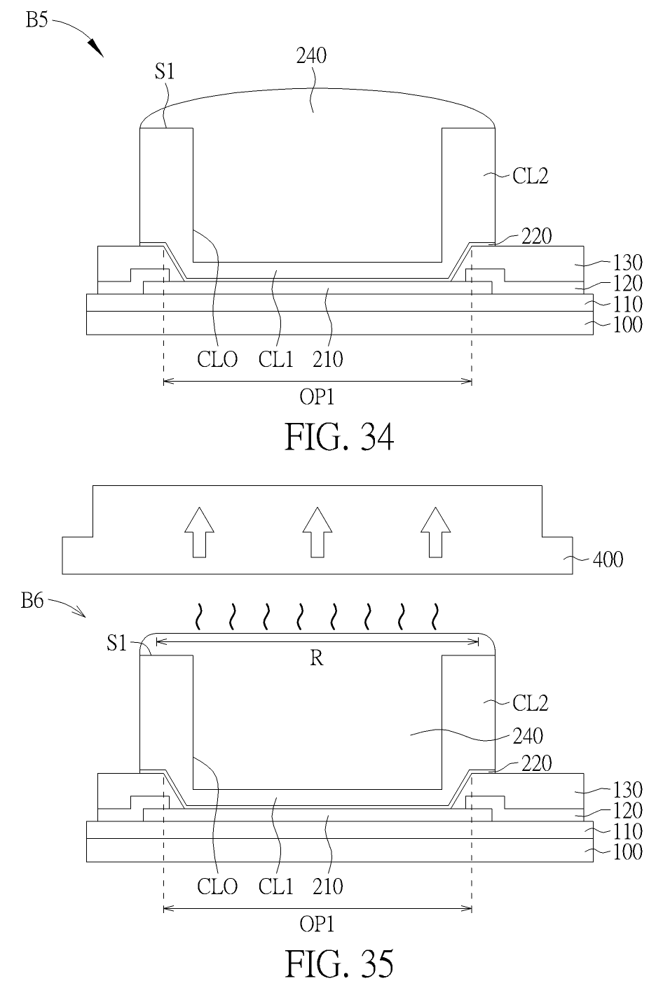

As shown in FIG. 34, a reflow process is then performed to form the solder bump 240 within the opening CLO defined by the annular second copper layer CL2, thus completing the bump structure B5 in FIG. 22.

As shown in FIG. 35, the bump structure B5 in FIG. 34 can be further subjected to a bump hot pressing process, in which a jig (as shown in FIGS. 7-8) is used to press the solder bump 240 at a predetermined temperature, softening and pressing down the already formed solder bump 240, thereby forming a flat top surface area R on the solder bump 240, thus forming the bump structure B6 in FIG. 23.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate having a bump pad thereon;
a passivation layer disposed on the substrate, wherein the passivation layer covers a perimeter of the bump pad and has a slot-shaped opening exposing a central region of the bump pad;
an under bump metal (UBM) layer disposed on the central region of the bump pad; and
a solder bump disposed on the UBM layer, wherein the solder bump comprises a flat top surface area.

2. The semiconductor structure according to claim 1, wherein the slot-shaped opening has a length L and a width W, wherein an L/W ratio is equal to or greater than 1.

3. The semiconductor structure according to claim 1, wherein the solder bump further comprises a vertical sidewall.

4. The semiconductor structure according to claim 3, wherein the solder bump further comprises a rounded corner between the vertical sidewall and the flat top surface area.

5. The semiconductor structure according to claim 1, wherein the bump pad comprises an aluminum pad.

6. A method for forming a semiconductor structure, comprising:
providing a substrate having a bump pad thereon;
forming a passivation layer on the substrate, wherein the passivation layer covers a perimeter of the bump pad and has a slot-shaped opening exposing a central region of the bump pad;
forming an under bump metal (UBM) layer on the central region of the bump pad;
forming a solder bump on the UBM layer;
subjecting the solder bump to a re-flow process; and
after the re-flow process, pressing the solder bump with a jig at a predetermined temperature thereby forming a flat top surface area on the solder bump.

7. The method according to claim 6, wherein the slot-shaped opening has a length L and a width W, wherein an L/W ratio is equal to or greater than 1.

8. The method according to claim 6, wherein the solder bump further comprises a vertical sidewall.

9. The method according to claim 8, wherein the solder bump further comprises a rounded corner between the vertical sidewall and the flat top surface area.

10. The method according to claim 6, wherein the bump pad comprises an aluminum pad.

11. The method according to claim 6, wherein the predetermined temperature is between 250-280 degrees Celsius.

12. A semiconductor structure, comprising:
a substrate having a bump pad thereon;
a first passivation layer disposed on the substrate, wherein the first passivation layer covers a perimeter of the bump pad and has a first slot-shaped opening exposing a central region of the bump pad;
a second passivation layer disposed on the first passivation layer, wherein the second passivation layer has a second slot-shaped opening overlapping with the first slot-shaped opening, wherein the second slot-shaped opening has a dimension that is greater than a dimension of the first slot-shaped opening;
an under bump metal (UBM) layer disposed on the central region of the bump pad; and
a solder bump filled into the first slot-shaped opening and the second slot-shaped opening.

13. The semiconductor structure according to claim 12, wherein the slot-shaped opening has a length L and a width W, wherein an L/W ratio is equal to or greater than 1.

14. The semiconductor structure according to claim 12, wherein the second slot-shaped opening is concentric and completely overlapped with the first slot-shaped opening.

15. The semiconductor structure according to claim 12, wherein a step structure is provided between the second slot-shaped opening and the first slot-shaped opening.

16. The semiconductor structure according to claim 12, wherein the second passivation layer has a declined sidewall around the second slot-shaped opening, and wherein the UBM layer covers the declined sidewall.

17. A semiconductor structure, comprising:
a substrate having a bump pad thereon;
a passivation layer disposed on the substrate, wherein the passivation layer covers a perimeter of the bump pad and has a slot-shaped opening exposing a central region of the bump pad;
a first copper layer disposed on the bump pad;
an annular second copper layer disposed along the perimeter of the bump pad, wherein the annular second copper layer partially overlaps the first copper layer, and wherein an opening is defined by the annular second copper layer; and
a solder bump filled into the opening.

18. The semiconductor structure according to claim 17, wherein the slot-shaped opening has a length L and a width W, wherein an L/W ratio is equal to or greater than 1.

19. The semiconductor structure according to claim 17, wherein the solder bump extends onto a top surface of the annular second copper layer.

20. The semiconductor structure according to claim 17, wherein a thickness of the annular second copper layer is greater than a thickness of the first copper layer.
